(19) United States
(12) Patent Application Publication
(10) Pub. No.: US 2004/0113705 A1
(43) Pub. Date: Jun. 17, 2004

(54) Integrated self-tuning L-C filter

(75) Inventor: David H. Shen, Saratoga, CA (US)

Correspondence Address: DAVID H. SHEN, IRF Semiconductor, Inc., 6 RESULTS WAY, CUPERTINO, CA, 95014, US

(73) Assignee: IRF SEMICONDUCTOR, INC.

(21) Appl. No.: 10/729,661

(22) Filed: Dec. 5, 2003

Related U.S. Application Data
(60) Provisional application No. 60/431,972, filed on Dec. 10, 2002.

(51) Int. Cl. H03L 7/00

(52) U.S. Cl. 331/17

(57) ABSTRACT

A method for tuning an on-chip L-C filter is disclosed which permits greater integration on standard silicon chips and greater insensitivity to manufacturing and ambient temperature variations. The L-C filter is tuned by a phase-locked loop with a L-C based VCO. The tuning loop can be powered down to save power and reduce noise coupling. The L-C filter can be operated continuously.

THIS APPLICATION IS BASED ON THE PROVISIONAL APPLICATION No. 60/431,972 FILED ON Dec. 10, 2002

### REFERENCE

[1] Li, D. & Tsividis Y., Dig. of Tech. Papers, International Solid-State Circuits Conference, February 2001, pp 368-369.

### BACKGROUND

1. Technical Field of Invention

The present invention relates to a method of integrating accurate on-chip L-C filters by using a tuning mechanism to compensate for manufacturing and ambient temperature variations of on-chip components. These tuned filters can find applications in integrated radio frequency receiver and transmitters.

2. Background of the Invention and Discussion of Prior Art

At the present time, one of the main barriers in integrating RF communications receivers is the inability to repeatedly manufacture filters with accurate cut-off frequencies. FIG. 1 describes an important class of filters based on a network of inductors (L), 1 and 2, and capacitors (C), 3 and 4, known as L-C filters. The filter acts upon voltage input, 5, to produce a filtered voltage output, 6. The design of these types of filters is well known in the art. However, both inductors and capacitors are sensitive to processing variations during the manufacturing of integrated circuits. These variations prevent the filter response from being consistently and accurately manufactured.

Other types of filters known as active filters are based on active circuits, resistors and capacitors. However, at high frequencies, active filters have degraded filter responses and noise performance compared to L-C filters.

One method of tuning L-C filtering based on time multiplexing between a tuning circuit and a filtering circuit has been described in [1]. This method will not work for systems that have continuous filtering requirements.

### OBJECTS AND ADVANTAGES OF THE INVENTION

Accordingly, it is a primary object of the present invention to provide a self-tuning L-C filter topology that is insensitive to manufacturing and ambient temperature variations and is able to operate continuously.

### SUMMARY OF THE INVENTION

The present invention achieves the above objects and advantages by providing a new method for designing a L-C filter network without sensitivity to manufacturing and ambient temperature variations and able to maintain a continuous filter response.

### DESCRIPTION OF DRAWINGS

FIG. 1 is a diagram of a prior art L-C filter network.

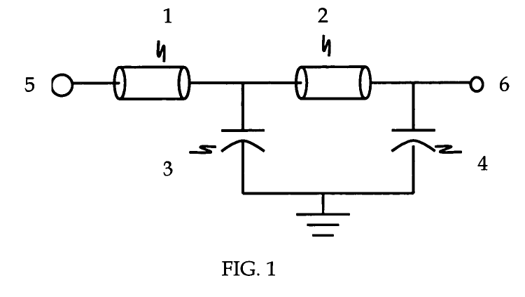

FIG. 2 is a block diagram of the self-tuning L-C filter network.

FIG. 3 is an example of an L-C based voltage-controlled oscillator.

FIG. 4 is a diagram of the tunable main L-C filter network.

### DESCRIPTION OF THE PREFERRED EMBODIMENT

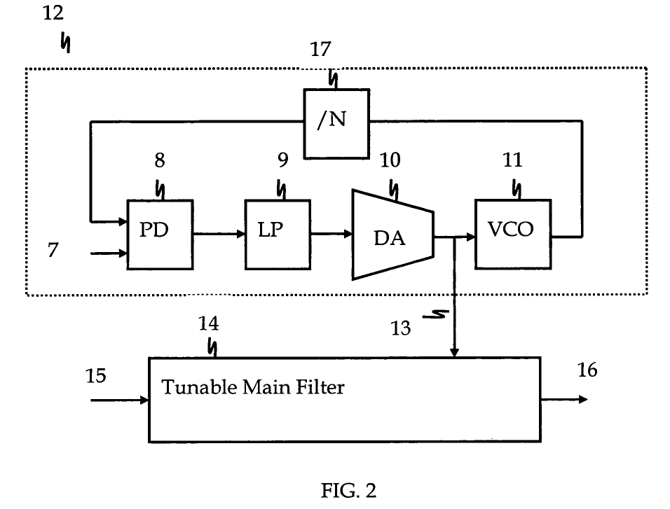

FIG. 2 is a block diagram of the self-tuning L-C filter network consisting of a main L-C filter, 14, that is tunable, and a phase-locked loop forming the basis of the L-C tuning circuit, 12. The tunable main L-C filter, 14, has input voltage, 15, and filtered output voltage 16. A tuning voltage, 13, is used to control the tuning of capacitors in the L-C filter. The phase-locked loop, 12, consists of a fixed reference frequency input, 7, phase-frequency detector, 8, digital loop filter, 9, digital-to-analog converter, 10, and L-C based voltage-controlled oscillator (VCO), 11, and feedback frequency divider, 17. The operation of phase-locked loops is well known in the art. The phase-frequency detector, 8, compares the frequency of the reference frequency input, 7, with the output of the frequency divider, 17. The digital loop filter, 9, integrates the error signal from the phase-frequency detector, 8. The digital output of the digital loop filter, 9, is then used to drive the input of the digital-to-analog converter, 10. The analog output of the digital-to-analog converter, 10, drives the tuning voltage, 13, of the VCO, 11, as well as the tuning voltage, 13, of the main L-C filter, 14. After the phase-locked loop is powered up and locked, it can be shut down. The value of the digital loop filter is saved in digital registers to control the value of the tuning voltage, 13, after the phase-locked loop is shut down. Shutting down the tuning loop has several advantages: It eliminates noise coupling from the tuning loop into other circuits; it allows continuous filtering without additional tuning; and it allows power to be minimized.

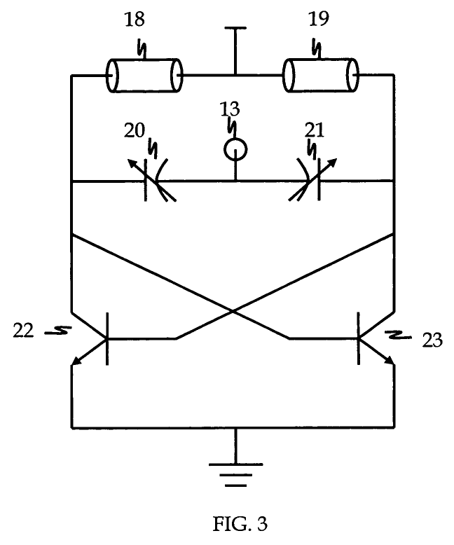

FIG. 3 is a diagram of a possible implementation of the VCO. The VCO consists of active elements, 22 and 23, such as bipolar or MOS transistors as well as passive inductors, 18 and 19, with tunable capacitor elements, 20 and 21. A tuning voltage, 13, is an input that can be used to vary the value of the capacitor elements, 20 and 21. Those skilled in the art will recognize that there are many possible implementations of the VCO as well as many possible implementations of the tunable capacitor elements, 20 and 21.

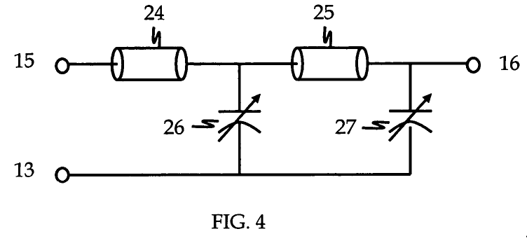

FIG. 4 is a diagram of one possible main L-C filter network that can be tuned. The input voltage, 15, is filtered to produce output voltage, 16. The filter consists of inductor elements, 24 and 25, and capacitor elements, 26 and 27. The tuning voltage, 13, is an input that can be used vary the value of the tunable capacitor elements, 26 and 27, so that manufacturing and temperature variations can be removed. In order to obtain the greater insensitivity to manufacturing process variations, the capacitors elements, 26 and 27, in the L-C filter should have similar physical dimensions and layout to the capacitor elements, 20 and 21, in the VCO, and the inductor elements, 24 and 25, in the filter should have similar physical dimensions and layout to the inductor elements, 18 and 19, in the VCO. Those skilled in the art will recognize that there are many possible L-C filter networks that can be designed with fewer or more inductors, capacitors, or resistors than the preferred embodiment.

These and other modifications, which are obvious to those skilled in the art, are intended to be included within the scope of the present invention. Accordingly, the scope of the invention should be determined not by the embodiment described, but by the appended claims and their legal equivalents.

1. A method for self-tuning an L-C filter network comprising
A phase-frequency detector with a fixed reference frequency input and a frequency-divided oscillator input. The output of the phase detector is connected to
A digital loop filter whose output is connected to
A digital-to-analog converter that generates a voltage to tune the capacitors of
A voltage-controlled oscillator based on an L-C resonant circuit. The output of the voltage-controlled oscillator connect to
A frequency divider whose output connects to an input of the phase detector.
A L-C filter network comprising a tunable main L-C filter wherein the capacitors in the filter are controlled by a tuning voltage that is used to tune the voltage-controlled oscillator.

2. The method of claim 1 wherein the tunable capacitors are based on varactors.

3. The method of claim 1 wherein the tunable capacitors are based on MOS capacitors.

4. The method of claim 1 wherein the inductors are based on on-chip spiral inductors.

5. The method of claim 1 wherein the inductors are based on bonding wires.

6. The method of claim 1 wherein the phase-locked looped can be powered down, and the value of the loop filter output can continue to tune the main L-C filter.

7. The method of claim 1 wherein the main L-C filter is a ladder type.

8. The method of claim 1 wherein the main L-C filter is a two-pole resonant circuit.

9. The method of claim 1 wherein the main L-C filter forms a low-pass filter.

10. The method of claim 1 wherein the main L-C filter forms a high-pass filter.

11. The method of claim 1 wherein the main L-C filter forms a band-pass filter.

12. The method of claim 1 wherein the main L-C filter forms a band-stop filter.

13. The method of claim 1 wherein the main L-C filter is used in a radio frequency system.

14. The method of claim 1 wherein the circuits are implemented in a CMOS technology.

15. The method of claim 1 wherein the circuits are implemented in a bipolar technology.

16. The method of claim 1 wherein the circuits are implemented in other semiconductor process technologies.

17. The method of claim 1 wherein the digital loop filter is implemented by a digital counter.

18. The method of claim 1 wherein the L-C filter includes resistors.

19. The method of claim 1 wherein the number of capacitor elements in the main L-C filter are N, where N is an integer.

20. The method of claim 1 wherein the number of inductor elements in the main L-C filter are M, where M is an integer.

21. The method of claim 1 wherein the number of resistor elements in the main L-C filter are J, where J is an integer.

22. The method of claim 1 wherein the tuning voltage is used to control multiple L-C filter networks.

23. The method of claim 1 wherein the circuits are fully differential.

24. The method of claim 1 wherein the circuits are single-ended.
